(19) United States
(12) Patent Application Publication
(10) Pub. No.: US 2005/0213772 A1
(43) Pub. Date: Sep. 29, 2005

(54) Method and apparatus for reverberation processing

(76) Inventor: Yiou-Wen Cheng, Shu Lin City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 10/809,753

(22) Filed: Mar. 25, 2004

(51) Int. Cl. H03G 3/00; G10H 1/02

(52) U.S. Cl. 381/63; 84/630

(57) ABSTRACT

A method and an apparatus for reverberation processing, mainly utilizing a fact that a human's hearing can identify the audio quality in 50 ms, and combines a high quality filter module and a low quality filter module. The high quality filter module will produce audio signals with high quality reverberation effects in a finite period of time from the beginning; after that the reverberation effects are provided by the low quality filter module. Therefore, reverberation effects with long duration, simpler hardware and superior quality can be reached.

### BACKGROUND OF THE INVENTION

1. Field of the Invention

The present invention is a method and an apparatus for reverberation processing, and especially relates to a reverberation processing device comprising a high quality filter module and a low quality filter module, in which the reverberation generated in a limited period at beginning is provided by the high quality filter module.

2. Description of Related Art

In recent years, audio playing devices generate sound with 3D effect to users, where the sound is perceived as real and virtual reality is created.

Sound with 3D effects is usually made by man via providing artificial reverberations. In general, natural reverberations are echoes and resonance of sounds generated in a specific environment and the reverberations will decay with time. Artificial reverberation can be made by filters. According to different reverberation characteristics and delay times, various filters can be devised and the reverberations can be generated via using the filters to perform convolution calculations with an original sound The filters are classified into two categories, i.e. finite impulse response filter (FIR filter) and infinite impulse response filter (IIR filter).

The FIR filter is devised primarily via measuring environmental reverberations. Since it has finite impulse responses, the FIR filter can provide the realest reverberation effects. However, having higher calculation complexity is the drawback of the FIR filters. FIG. 1 shows a block diagram of a conventional FIR filter used for reverberation processing. Therein, the delay units 10 are used to simulate a special effect of the early reflection in free space. The sampling speed is 48k per second, and about 100 thousand points of convolution calculations need to be performed in every three seconds. Therefore, the FIR filter 50 needs numerous cascaded delay units 10 for sampling. Hence, it will cause the circuit designs more complicated and the processing speed much lower.

IIR filters are all pass filters and can produce infinite reverberation impulse responses. Although the IIR filters have lower calculation complexity, the reverberations produced by the IIR filter are unnatural. As shown in FIG. 2, the IIR filter only employs a power amplifier 75 to feedback the signals to produce the reverberation impulse responses infinitely. Hence, the structure and calculation of the circuit shown in FIG. 2 are simpler than that of the FIR filters obviously. However, the correlation between the signals generated by the IIR filters 100 is larger so that the produced reverberations are more unnatural.

As described above, the conventional apparatuses for reverberation processing still have drawbacks obviously. The apparatus using FIR filter can produce a high sound quality but its cost is also high. The apparatus using IIR filters may has lower calculation complexity and simpler structure, but it can't produce realer reverberation.

### SUMMARY OF THE INVENTION

The object of the present invention is to provide a method and an apparatus for reverberation processing. Since human can identify reverberations of the audio signals only during a finite period of time. The method of the present invention has following steps: providing a high quality filter module and a low quality filter module; inputting an audio signal into the high quality filter module for generating a high quality reverberation in a limited period; inputting the audio signal to the low quality filter module for generating a low quality reverberation with unlimited length; delaying the reverberation generated by the low quality filter module; and combining the high and low quality reverberations generated by the high quality filter module and the low quality filter module.

Numerous additional features, benefits and details of the present invention are described in the detailed description, which follows.

### BRIEF DESCRIPTION OF THE DRAWINGS

The various objects and advantages of the present invention will be more readily understood from the following detailed description when read in conjunction with the appended drawing, in which:

FIG. 1 shows a block diagram of a prior art FIR filter;

FIG. 2 shows a block diagram of a prior art IIR filter;

FIG. 3 shows a block diagram of a device for reverberation processing in accordance with the present invention;

FIG. 4 shows a time curve diagram of signals in the present invention; and

FIG. 5 shows a flow diagram of a method for reverberation processing in accordance with the present invention.

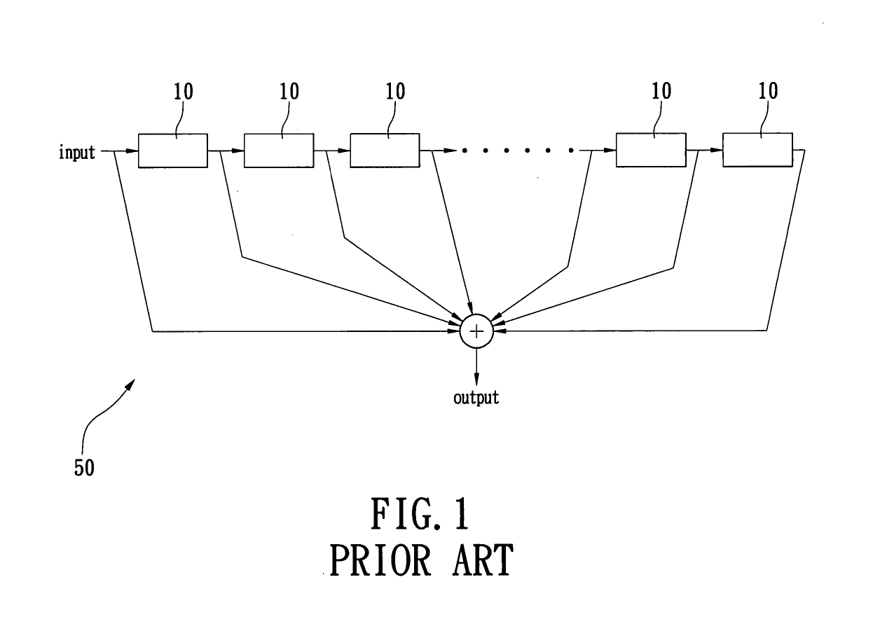

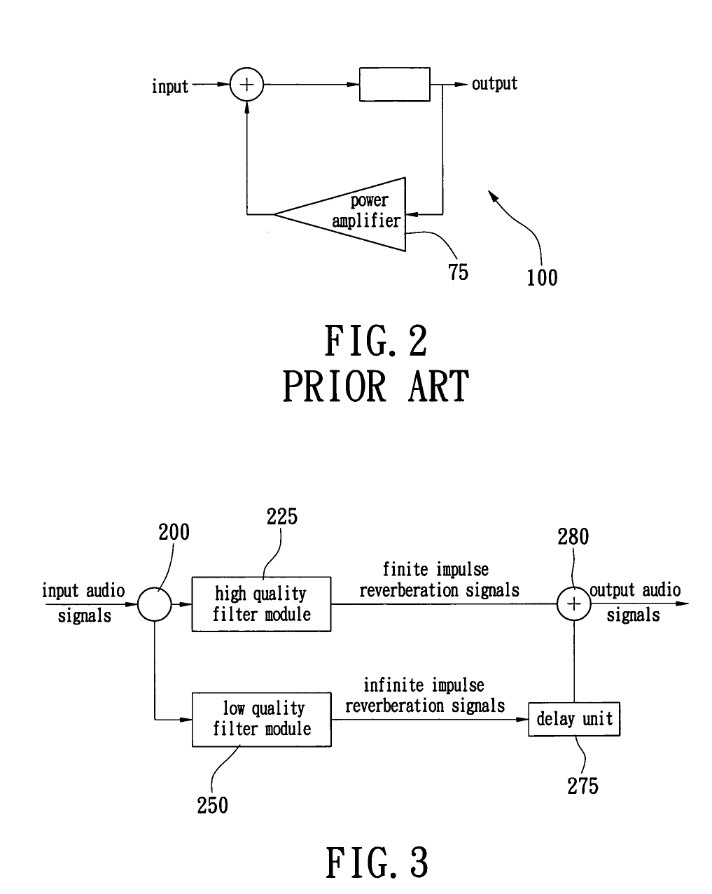

### DETAILED DESCRIPTION OF PREFERRED EMBODIMENTS

The present invention proposes a reverberation processing device and method having the common advantages of the high quality and low quality filter modules so that it can give consideration to the sound quality and processing speed of the reverberation signals. FIG. 3 shows the block diagram of a reverberation processing device in accordance with the present invention. A common input terminal 200 receives audio signals and then inputs the audio signals into a high-quality filter module 225 and a low-quality filter module 250, respectively. In this embodiment of the present invention, the high quality filter module 225 may be a FIR filter and the low quality filter module 250 may be an IIR filter.

Only during a finite period of time can a human identify the reverberation effects in the audio signals, and the finite period of time is about 50 ms according to a report of a latest experiment. Therefore, the high quality filter module 225 is used to process the input audio signals for 50 ms. Many calculations in using the high quality filter module 225 are needed; if the high quality filter module 225 is used for only 50 ms, the amounts of calculations and sampling points for convolution calculations will be significantly fewer; thus, the circuit may be simplified. After 50 ms, the audio signals are input into the low quality filter module 250. Although the effects made by the low quality filter module 250 are inferior to those made by the high quality filter module 225, human cannot differentiate between the reverberation effects after 50 ms and the reverberation effects lasting infinitely. Because points in convolution calculations are much fewer for a processing time of only 50 ms, processing speed of the circuit is improved, and the quantity of memory needed for storing the calculation results is much smaller.

The high quality filter module 225 generates audio signals with high quality reverberation effects and the signals will last for a finite period T. After that, the high quality audio signals are immediately sent to an adder 280. Users can hear the high quality audio signals output from the adder at first time and thereby differentiate the echo and resonance of the sounds.

The low quality filter module 250 will generate infinite length audio signals with low quality reverberation effects. However, the low quality filter module 250 may be connected to a delay unit 275, and the audio signals will be delayed for a period of time K. Next, the audio signals are also sent to the adder 280 and combined with the above-mentioned high quality audio signals. Users will not hear the delayed low quality reverberation effects at first; and the delay unit 275 can be connected behind or in front of the low quality filter module 250.

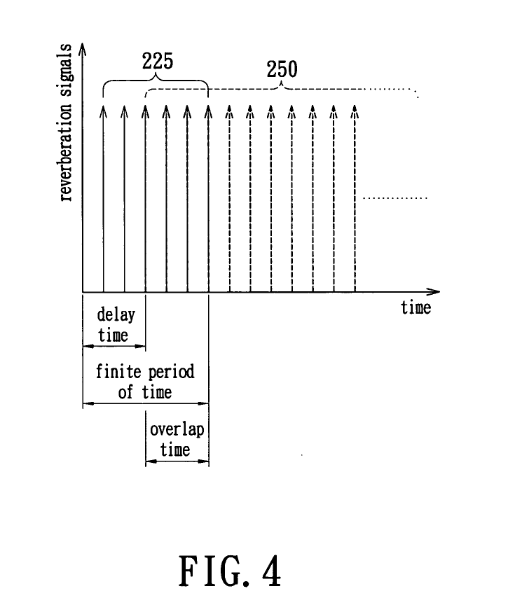

FIG. 4 shows a timing diagram of signals in the present invention. In the beginning of the time, the signals with reverberation effects are provided by the high quality filter module 225, and the signals will last for a finite period of time T. The other audio signals are processed by the delay unit 275 first, and then output by the low quality filter module 250 after a delay time K (the delay time K may last for 25 ms to 45 ms). There always exists an overlap time (T-K) to prevent the interruption of the audio signals with reverberation effects. Before the finite audio signals vanish, the infinite audio signals overlap with the finite audio signals; therefore, users will not feel a drop when listening the audio signals.

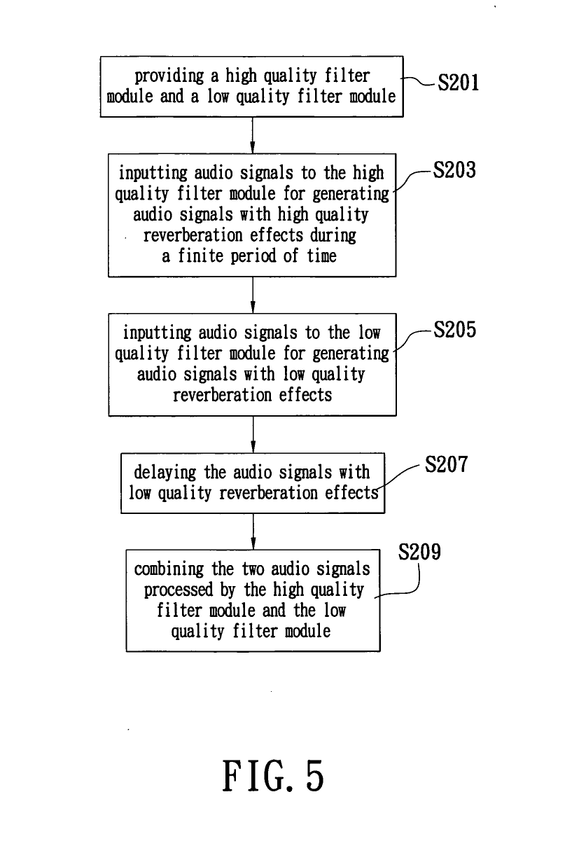

FIG. 5 shows a flow chart of a reverberation processing method of the present invention. The steps are: providing a high quality filter module 225 and a low quality filter module 250 (S201); inputting audio signals into the high quality filter module 225 for generating audio signals with high quality reverberation effects during a finite period of time (S203); meanwhile, inputting audio signals into the low quality filter module 250 for generating audio signals with low quality reverberation effects (S205); delaying the audio signals with low quality reverberation effects (S207), in which users will hear the sound output from the high quality filter module 225 first; and finally, combining the two audio signals processed by the high quality filter module 225 and the low quality filter module 250. Following the abovementioned steps, the reverberation effects will be made first by the high quality filter module 225 during a finite period of time T.

Although the present invention has been described with reference to the preferred embodiment therefore, it will be understood that the invention is not limited to the details thereof. Various substitutions and modifications have suggested in the foregoing description, and other will occur to those of ordinary skill in the art. Therefore, all such substitutions and modifications are intended to be embrace within the scope of the invention as defined in the appended claims.

1. A method for reverberation processing, comprising:
providing a high quality filter module and a low quality filter module;
inputting an audio signal into the high quality filter module for generating a high quality reverberation in a limited period;
inputting the audio signal to the low quality filter module for generating a low quality reverberation with unlimited length;
delaying the reverberation generated by the low quality filter module; and
combining the high and low quality reverberations generated by the high quality filter module and the low quality filter module.

2. The method of claim 1, wherein the step of providing the high quality filter module is providing a finite impulse response filter (FIR filter).

3. The method as claimed in claim 1, wherein the step of providing the low quality filter module is providing an infinite impulse response filter (IIR filter).

4. The method as claimed in claim 1, wherein the step of delaying the reverberation generated by the low quality filter module is achieved by using a delay unit.

5. The method as claimed in claim 1, wherein in the step of combining the high and low quality reverberations generated by the high quality filter module and the low quality filter module, the high and low quality reverberations can be generated in an overlapped way.

6. The method as claimed in claim 1, wherein the step of combining the high and low quality reverberations generated by the high quality filter module and the low quality filter module is achieved by using an adder.

7. The method as claimed in claim 1, wherein in the step of inputting an audio signal to the high quality filter module, the limited period is the beginning 50 ms.

8. A reverberation processing apparatus provided with a common input terminal for receiving an audio signal, comprising:
a high quality filter module connected to the common input terminal and receive the audio signals for generating high quality reverberation effects lasting for a finite period of time;
a low quality filter module connected to the common input terminal and receiving the audio signals for generating low quality reverberation effects lasting for a infinite period of time; and
a delay unit connected to the low quality filter module to delay a time of the audio signals with low quality reverberation effects.

9. The reverberation processing apparatus as claimed in claim 8, wherein the finite period of time is about 50 ms.

10. The reverberation processing apparatus as claimed in claim 8, wherein the high quality filter module is a FIR filter.

11. The reverberation processing apparatus as claimed in claim 8, wherein the low quality filter module is an IIR filter.

12. The reverberation processing apparatus as claimed in claim 8, wherein the delay time lasts for about 25 ms to 45 ms.

13. The reverberation processing apparatus as claimed in claim 8, wherein the two audio signals with low quality reverberation effects and high quality reverberation effects overlap after the delay time.

14. The reverberation processing apparatus as claimed in claim 8, wherein the two audio signals with low quality reverberation effects and high quality reverberation effects are combined by an adder.
